(19) United States
(12) Patent Application Publication
(10) Pub. No.: US 2008/0006098 A1
(43) Pub. Date: Jan. 10, 2008

(54) Sensor device and a method for its manufacturing

(75) Inventor: Michael Rogalli, Rottenburg (DE)

Correspondence Address: SCHWEGMAN, LUNDBERG & WOESSNER, P.A., P.O. BOX 2938, MINNEAPOLIS, MN, 55402, US

(73) Assignee: INFINEON TECHNOLOGIES, MUNCHEN (DE)

(21) Appl. No.: 11/482,518

(22) Filed: Jul. 7, 2006

(51) Int. Cl. G01P 15/00; G01L 1/00; H01L 21/00

(52) U.S. Cl. 73/862.625; 438/48; 257/E21.001

(57) ABSTRACT

A sensor device with a semiconductor substrate with at least one deformable region with a sensing element thereon that generates an output signal related to a force applied to the deformable region is shown. A wiring formed over the deformable region and deformable therewith has a deformation characteristic selected to reduce an output error characteristic of the sensor output signal. A method for manufacturing the sensor device is disclosed.

### BACKGROUND

The present invention deals with sensor devices having a deformable region and methods for manufacturing such sensor devices. Such sensor devices are generally used for measuring acceleration or pressure.

### BRIEF DESCRIPTION OF THE DRAWINGS

The accompanying drawings are included to provide a further understanding of the invention, and are incorporated in and constitute a part of this specification. The drawings illustrate embodiments of the present invention and together with the description serve to explain the principles of the invention. In the drawings,

FIG. 1 is a schematic cross-section of a possible embodiment of the invention;

FIG. 2 shows a schematic cross section through an embodiment of a wiring according to the invention; and

FIG. 3 shows a block diagram of a possible manufacturing method.

Reference will be made in detail to the embodiments of the invention, which are illustrated in the accompanying drawings. The following description relates to various embodiments based on which one skilled in the art will understand the invention. Nevertheless, one skilled in the art will appreciate that the invention is likewise applicable to further embodiments, which are covered by the scope of the accompanying claims.

### DETAILED DESCRIPTION

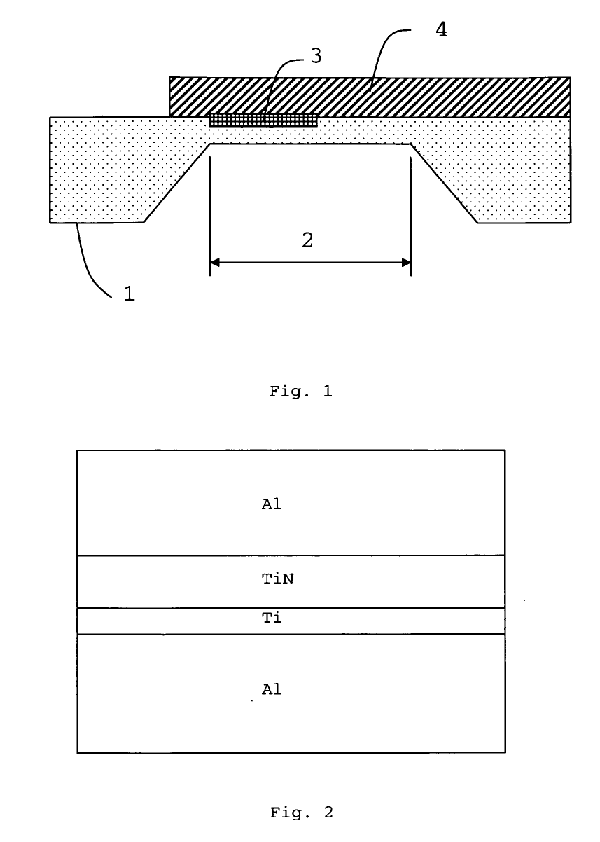

FIG. 1 shows a schematic cross section of a possible embodiment of the invention. It shows a silicon substrate 1, having a deformable region 2. The substrate can also be from any suitable semiconductor material other than silicon. The thickness of the substrate in the deformable region a referred as flexible membrane, is much smaller than outside of this region.

Thicknesses of the substrate inside and outside of the deformable region can vary substantially depending on embodiment of the invention.

A sensing element 3 on the substrate 1 is coupled to the deformable region 2 in such a way that any deformation of the substrate 1 in the deformable region results in a generation of an output signal related to a force applied to the deformable region and causing the said deformation.

As a sensing element 3 any kind of sensing element like piezo-element or a capacitive sensing element can be used.

FIG. 1 shows also a metal line or wiring 4 formed over the deformable region of the substrate. During the operation of sensor a conductive wiring on a chip surface for contacting a sensing element is used. The generated voltage can be e.g. conducted over the wiring to and processed by an application-specific integrated circuit (ASIC), the resulting voltage strongly depending on device design. The integrated circuit is calibrated for a given temperature and pressure range.

During the operation of the sensor any deformation of the deformable region of the substrate causes at least partial deformation of the wiring. The wiring has a deformation characteristic selected to reduce an output error characteristic of the sensor output signal.

In an embodiment of the invention four piezo-resistors as sensing elements are switched to a so called wheatstone bridge. The thermal residual stress in these metal lines produces a change of the values of the piezo-resistors with respect to the un-stressed state. If this change is not equal for the four piezo-resistors, it creates a supplementary voltage at the output of the Wheatstone bridge, interpreted as a change of the hydrostatic pressure applied on the membrane, thus making possible to measure the hydrostatic pressure of the surrounding atmosphere.

In the case of a pressure sensor device the deformable region of the substrate is to be deformable due to the environmental pressure on one side of the deformable region, while the other side of the deformable region being adjacent to a closed chamber, isolated from the environmental atmosphere.

The sensor device can be an acceleration sensor device, with the deformable region of the substrate being deformable due to inertial forces during an accelerated movement of the sensor device.

Due to the thermal mismatch between the substrate and the wiring a thermal residual stress exists in both materials at room temperature after the deposition of the metal onto a silicon wafer. The subsequent thermal cycling results in a change of tress in the metal wiring as a result of the thermal mismatch and the stress relaxation phenomenon.

After a given number of temperature and pressure cycles an intrinsic change of the wiring (yielding) can occur. Amongst other influencing factors this change strongly depends on the thickness of the used materials for the wiring. For typical thicknesses of 1 μm the consequence of the yielding is an electrical offset, causing a distortion in the measured signal. Because of the difference in the coefficient of thermal expansion (CTE) between Silicon and the conductive wiring a mechanical stress due to temperature and pressure is caused leading to a relaxation in the conductive wiring. A characteristic for this process is the yield limit. Choosing suitable wiring structure increases the yield limit substantially.

Using a suitable multilayered film for conductive wiring leads to mechanical decoupling of the separate layers and thus to increase of the yield limit without deteriorating the electrical performance of the wiring.

In some embodiments the wiring has at least two conductive layers.

In some embodiments one of the conductive layers is formed from one or more of the group consisting of aluminium, copper, titanium, gold, and of their alloys.

In an embodiment the wiring comprises an insulator layer, which can be put between two metal layers as an intermediate layer. As an intermediate layer a TiN-Layer of a thickness between 10 and 30 nm can be used.

In an embodiment an intermediate layer between the first metal layer and the second metal layer is formed.

In an embodiment a metal layer like Ti layer is used as an intermediate layer between the two metal layers with a thickness between 3 and 8 nm.

In an embodiment an overall thickness of the wiring is between 800 and 2000 nm.

In some embodiments at least one of the abovementioned layers is formed by sputtering.

In an embodiment the thickness of the first metal layer is chosen between 100 and 800 nm.

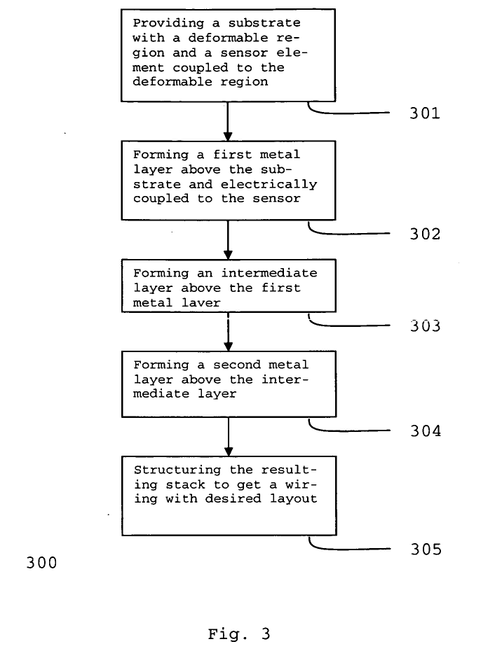

FIG. 2 shows a schematic cross section through an embodiment of a wiring according to the invention.

In an embodiment following thicknesses of different layers are chosen: Al top layer-475 nm, TiN layer-20 nm, Ti-5 nm, Al bottom layer-500 nm.

In an embodiment the overall thickness of the wiring in this embodiment is equal to 1000 nm.

In an embodiment the sensor device as shown in FIG. 1 is an acceleration sensor device, with the deformation region being deformable due to inertial forces during an accelerated movement of the sensor device.

In an embodiment the sensor device is a pressure sensor device, comprising a closed chamber on one side of the deformable region, while the second side of the deformable region being exposed to the atmospheric pressure or to a pressure of a gas surrounding the sensor device.

In an embodiment the sensing element in the sensor is a piezo resistive sensing element.

Another aspect of the invention is a process of manufacturing the sensor device.

FIG. 3 shows a block diagram of a manufacturing process 300 for making wiring according to embodiments of the present invention.

In the first process 301 a substrate with a deformable region and with a sensing element coupled to the deformable region is provided.

Afterwards, in the operation shown in block 302 a first metal layer is formed above the substrate and electrically coupled to the sensor.

As a material for the above-mentioned layers one or more of the group consisting of aluminium, copper, titanium, gold, and their alloys can be considered.

In the next process an intermediate layer above the first metal layer is formed.

Afterwards a second metal layer above the intermediate layer is formed, which is then structured in order to obtain a wiring with a desired layout.

As a material for the above-mentioned layers one or more of the group consisting of aluminium, copper, titanium, gold, and their alloys can be considered.

In order to form the above-mentioned layers different techniques of film formation can be used; for instance sputtering, chemical vapour deposition, evaporation etc.

During the manufacturing process described above the thickness of each layer can be chosen appropriately by choosing accordingly the power and duration of the layer deposition.

In another embodiment of the invention the metallization process for the conductive wiring is as follows.

First a first metal layer of AlCu with a thickness of some 500 nm is deposited. Instead of AlCu layer an Al layer can used. Besides all materials mentioned in the description of FIG. 2 can be applied.

The thickness of the first metal layer can be chosen between 100 and 800 nm.

a Ti(5 nm)/TiN(20 nm) is sputtered. Afterwards the second layer of AlCu respectively is deposited till a desired final total thickness of some 1000 is achieved.

Afterwards a further structuring of the obtained wiring is done. For structuring such structuring techniques as photolithography with etching can be applied.

1. A Sensor Device, comprising:
a semiconductor substrate with at least one deformable region with a sensing element thereon that generates an output signal related to a force applied to the deformable region; and
wiring formed over the deformable region and deformable therewith, the wiring having a deformation characteristic selected to reduce an output error characteristic of the sensor output signal.

2. A sensor device according to claim 1, wherein the wiring comprises at least two conductive layers.

3. A sensor device according to claim 2, wherein one of the conductive layers is a conductor formed from one or more of the group consisting of aluminium, copper, titanium, gold, and of their alloys.

4. A sensor device according to claim 3, wherein the wiring comprises at least one TiN layer.

5. A sensor device according to claim 4, with a TiN layer thickness between 10 and 30 nm.

6. A sensor device according to claim 3, with at least one Ti layer with a thickness between 3 and 8 nm.

7. A sensor device according to claim 4, with a TiN layer thickness between 10 and 30 nm and with Ti layer with a thickness between 3 and 8 nm.

8. A sensor device according to claim 1 with an overall thickness of the wiring between 800 and 2000 nm.

9. A sensor device according the claim 1, wherein the sensor device is an acceleration sensor device, with the deformable region being deformable due to inertial forces during an accelerated movement of the sensor device.

10. A sensor device according to claim 1, wherein the sensor device is a pressure sensor device, comprising a closed chamber on one side of the deformable region, while the second side of the deformable region being exposed to the atmospheric pressure.

11. A process of manufacturing a sensor device, comprising:
providing a substrate with a deformable region and a sensor element coupled to the deformable region;
forming a first metal layer above the substrate and electrically coupled to the sensor;
forming an intermediate layer above the first metal layer; and
forming a second metal layer above the intermediate layer.

12. The process of manufacturing a sensor device according to claim 11, wherein at least one of the first metal layer and the second metal layer is formed from one or more of the group consisting of aluminum, copper, gold and of their alloys.

13. Process of manufacturing a sensor device according to claim 11, with a thickness of the first metal layer between 100 and 800 nm.

14. Process of manufacturing a sensor device according to claim 11, wherein the intermediate layer comprises a Ti layer with a thickness between 2 and 8 nm.

15. Process of manufacturing a sensor device according to layer with a thickness between 10 and 30 nm.

16. The process of manufacturing a sensor device according to claim 11, wherein at least one layer is formed by sputtering.
